(19) United States
(12) Patent Application Publication
(10) Pub. No.: US 2024/0149525 A1
(43) Pub. Date: May 9, 2024

(54) OBJECT-RECEIVING DEVICE FOR A VEHICLE AND METHOD FOR MANUFACTURING SUCH A DEVICE

(71) Applicant: PSA AUTOMOBILES SA, Poissy (FR)

(72) Inventors: Stéphane RAVASSARD, Gometz la Ville (FR); Jérome BELTRAN, Bois Colombes (FR)

(21) Appl. No.: 18/546,694

(22) PCT Filed: Feb. 2, 2022
(86) PCT No.: PCT/FR2022/050199

§ 371 Date: Aug. 16, 2023

(30) Foreign Application Priority Data
Mar. 18, 2021 (FR) FR2102721

(51) Int. Cl. B29C 64/153; B29C 64/307; G06F 30/15

(52) U.S. Cl. CPC B29C 64/153; B29C 64/307; G06F 30/15

(57) ABSTRACT

The invention relates to an object-receiving device for a vehicle (10) and to the method for manufacturing same. The object-receiving device (11) is obtained by additive manufacturing via powder bed fusion and is formed from a flexible material. The device (11) comprises a lower part with a shape suitable for fitting so as to be held at least in part in a cup-holder support (100) of the vehicle (10); and an upper part formed on the lower part, the upper part being configured to receive and hold at least one object.

### CROSS-REFERENCE TO RELATED APPLICATIONS

This application is the US National Stage under 35 USC § 371 of International Application No. PCT/FR2022/050199, filed Feb. 2, 2022, which claims the priority of French application 2102721 filed on Mar. 18, 2021, the content (text, drawings and claims) of both said applications being incorporated by reference herein.

### BACKGROUND

The devices and methods described herein relate to an object receiving device for a vehicle and to the method for manufacturing such a system. An accessory for a vehicle that is intended to be inserted into a cup holder of the vehicle and to receive one or more objects is also described. More generally, interior design devices for vehicles, in particular motor vehicles, are described.

Most contemporary vehicles are fitted with one or more cup holder recesses. These one or more cup holders are, for example, arranged in the center console, in the dashboard or in the inner panel of a door.

While the primary function of a cup holder is to hold a cup or can, the cup holder is often used as general storage, for example to hold coins, a cell phone, keys, etc.

Since the dimensions of a cup holder are fixed, only some cups or cans can be properly fitted therein and held securely by the cup holder. In addition, small objects that are put therein are subject to the movements of the vehicle and move around inside the cup holder, which produces noise or results in these objects falling. It is also difficult to retrieve small objects that have fallen to the bottom of such a cup holder.

A cup holder is therefore of particularly limited use.

### SUMMARY

One object is to improve the possibilities for storing objects in a vehicle.

Another object is to diversify the use made of cup holder supports in a vehicle.

A first aspect relates to an object receiving device for a vehicle, the device being obtained by powder bed fusion additive manufacturing and being formed of a flexible material, the device comprising:
a lower portion shaped to fit securely at least partially into a cup holder support of the vehicle;
an upper portion formed on the lower portion, the upper portion being configured to receive and hold at least one object.

According to one alternative, the flexible material corresponds to a thermoplastic polyurethane.

According to another alternative, the upper portion comprises a frame surrounding a central portion, the frame having a rigidity that is greater than the rigidity of the central portion, the central portion being configured to receive and hold the at least one object.

According to another alternative, the central portion comprises a set of striations formed parallel to one another.

According to another alternative, the central portion comprises a plurality of compartments of different sizes and/or shapes.

According to another alternative, the central portion has a cylindrical shape with a diameter smaller than the diameter of the cup holder support.

According to another alternative, the upper portion comprises a solid bottom separating the upper portion from the lower portion.

According to another alternative, the central portion has a lattice structure.

A second aspect relates to a vehicle, for example a motor vehicle, comprising a device as described hereinbefore according to the first aspect.

A third aspect relates to a method for manufacturing the object receiving device for a vehicle as described hereinbefore according to the first aspect, the manufacturing method comprising the following steps:
receiving data representative of a three-dimensional model of the object receiving device;
depositing a powder bed on a build platform to form a powder layer;
scanning the powder layer with a laser controlled according to the data;
lowering the build platform by a height corresponding to a layer height;
depositing a new powder bed on the scanned powder layer;
repeating the scanning, lowering and new deposition steps until the last powder layer is deposited and the last powder layer is scanned.

### BRIEF DESCRIPTION OF THE FIGURES

Other features and advantages will become apparent from the description of non-limiting embodiments hereinafter, with reference to the appended FIGS. 1 to 5, in which:

FIG. 1 schematically illustrates a portion of a passenger compartment of a vehicle according to one particular embodiment.

FIG. 2 schematically illustrates an object receiving device installed in the passenger compartment of FIG. 1 according to a first particular embodiment.

FIG. 3 schematically illustrates an object receiving device installed in the passenger compartment of FIG. 1 according to a second particular embodiment,

FIG. 4 schematically illustrates an object receiving device installed in the passenger compartment of FIG. 1 according to a third particular embodiment.

FIG. 5 is a flowchart of the various steps of a method for manufacturing the object receiving device according to one of FIGS. 2 to 4 according to one particular embodiment.

### DETAILED DESCRIPTION

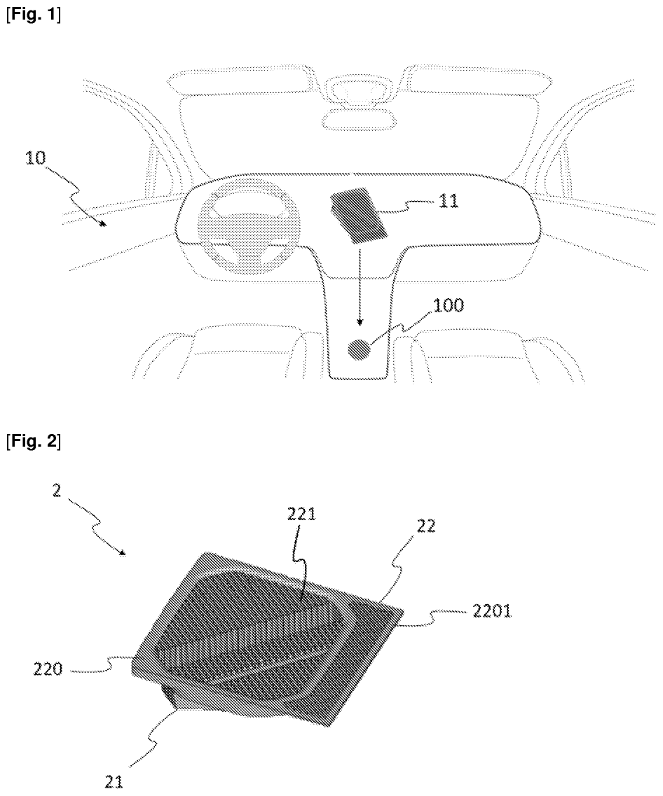

An object receiving device for a vehicle and the method for manufacturing same will now be described hereinafter with reference to FIGS. 1 to 5. Elements that are the same are denoted by the same reference signs throughout the following description.

FIG. 1 schematically illustrates a portion of a passenger compartment of a vehicle 10 according to one particular and non-limiting embodiment.

FIG. 1 shows a view of the interior of a vehicle 10, in particular of the front portion of the passenger compartment of the vehicle 10 which comprises, in particular, the steering wheel and the dashboard of the vehicle 10.

The vehicle 10 corresponds, for example, to a vehicle with a combustion engine, one or more electric motors or else a hybrid vehicle with a combustion engine and one or more electric motors. The vehicle 10 thus corresponds, for example, to a land vehicle, for example a car, a truck, or a coach.

The vehicle 10 comprises a cup holder support 100 (also called a container holder) arranged in the center console of the vehicle 10. The cup holder support 100 corresponds, for example, to a well forming a receptacle that is arranged to receive a cup (or a can or bottle) inserted vertically following the arrow.

According to another example, the vehicle 10 comprises two cup holders arranged next to one another in the center console.

According to one alternative embodiment, one or more cup holders are arranged in the dashboard of the vehicle, in addition to or instead of the one or more cup holders of the center console. Of course, the location of the arrangement of such a cup holder support is not limited to the examples above, but extends to any location in the passenger compartment of the vehicle 10.

An object receiving device 11 is advantageously installed in the vehicle 10, this object receiving device 11 being configured to fit into the cup holder support 100 in a vertical direction of insertion following the arrow.

The object receiving device 11 is, for example, manufactured according to a selective laser sintering (SLS) method. Such a manufacturing method makes it possible to produce 3D (three-dimensional) objects by depositing layers of powder on top of one another and one after the other as the process progresses, each layer being subjected to laser radiation which sinters or fuses the powder according to a 3D model by virtue of the energy from the laser (between 200 and 400 W for example), such as a CO₂ laser for example. The object receiving device 11 is printed in one run, i.e. as one piece, and no assembly of the various parts forming the object receiving device 11 is required at the end of the printing process. Selective laser sintering has the advantage of making it possible to print systems or parts with complex geometries via the implementation of 3D modeling techniques such as topological optimization for example. Such a process allows the manufacturing and assembly costs of the support system 100 to be reduced.

According to another example, the object receiving device 11 is obtained or manufactured according to a method implementing a multi jet fusion (MJF) method, for example the HP MJF method, which is implemented by a machine from Hewlett-Packard®, the company behind the MJF method. Unlike the SLS technique, the powder is brought to its melting point in the MJF method while retaining the principle of depositing successive layers of powder in order to print the entire device 11 in a single run, rather than portion by portion. Moreover, in the MJF method, the powder is melted by using a binder subjected to infrared radiation. For example, a liquid binder is sprayed (for example in the form of 80 μm droplets) onto a powder bed, which solidifies layer by layer to form the final system at the end of the process. The MJF method, and more particularly the HP MJF method, allows a significant increase in productivity in comparison with the SLS method.

The object receiving device 11 is advantageously made or manufactured from a flexible material, for example a thermoplastic elastomer or more particularly a thermoplastic polyurethane (TPU). A TPU has the advantage of combining the elastic properties of elastomers with the mechanical properties of plastics. In particular, a TPU has very good resistance to abrasion and wear.

Examples of such object receiving devices 11 are described in greater detail with reference to FIGS. 2, 3 and 4.

FIG. 2 schematically illustrates a device 2 for receiving items according to a first particular and non-limiting embodiment.

The device 2 is formed of a lower portion 21 configured to slot into the cup holder support 100 and an upper portion 22 which closes the upper opening off from the cup holder support 100. The lower portion 21 and the upper portion 22 are produced or manufactured by powder bed fusion additive manufacturing, as one piece.

The lower portion 21 is shaped to fit securely into a cup holder support of said vehicle 100. For example, the lower portion 21 has a circular or rectangular cross section. This lower portion 21 is, for example, fitted or slotted into the cup holder support, the fitting or slotting thereof therein being facilitated by the ability of the lower portion to deform elastically in order to conform to the shape of the cup holder support 100 during insertion, the device 2 being held in the cup holder support 100 by fitting snugly therein. For example, the lower portion 21 is inserted to a determined height in the cup holder, for example to a height of 2, 3, 4 or 5 centimeters. According to one alternative, the height of the lower portion is equal to the depth of the cup holder support, or is slightly less than the latter, so as to be inserted to the full depth of the cup holder support.

By virtue of the elastic properties of TPU, the device 2 is easily inserted into the cup holder support 100 and can also be easily removed from the cup holder support 100 as desired, without any particular effort from a user. The device 2 advantageously corresponds to a device that is removable and repositionable as desired.

The lower portion 21 advantageously corresponds to a hollow element formed of a shell with a thickness from one to multiple millimeters for example. According to one alternative, lateral reinforcements are produced on the inner contour of the shell during the 3D printing of the device 2 to ensure better retention of the lower portion 21 in the cup holder support, these reinforcements corresponding, for example, to strips of material forming portions of greater thickness over the height of the inner contour of the shell.

The upper portion 22 advantageously rests on the lower portion 21, the upper portion 22 corresponding to the visible portion of the device 2 when the device is slotted into the cup holder 100.

The upper portion 22 is, for example, formed of a frame 220 surrounding a central portion 221 of the upper portion 22. The rigidity of the frame 220 is advantageously greater than that of the central portion 221. A higher rigidity is obtained by having a frame 220 whose thickness is greater than that of the central portion 221 for example.

The frame 220 advantageously has a portion 2201 formed on one end of the frame 220 on which particular patterns are printed according, for example, to the wishes of the user (personalizable portion). Such patterns correspond, for example, to text or a graphic element such as an icon or logo, these patterns being printed during the process of manufacturing the device 2 by 3D printing also referred to as additive manufacturing.

According to one alternative embodiment, the frame 220 is configured to rest on a surface formed around the mouth of the cup holder support 100, for example on the surface of the center console according to the example of FIG. 1 around the cup holder support. According to this alternative, the shape of the frame 220 is designed to match the surface on which it rests. According to another example, the frame is essentially planar in shape on its underside (i.e. the face resting on the surface surrounding the cup holder support) in order to be suitable for the greatest number of configurations and vehicles.

The central portion 221 is configured to receive one or more objects, for example a cell phone, credit cards, coins or any other objects. To that end and according to the particular example of FIG. 2, the central portion 221 comprises set of striations (or slats) formed parallel to one another, coins being able to be easily inserted into these striations for example. According to one alternative embodiment, the upper surface of this central portion, corresponding to the visible face once the device 2 has been slotted into the cup holder support, is smooth and does not comprise any pattern. According to this alternative, items received by this central portion 221 are held in place by virtue of the roughness of the upper surface which is obtained by the material used (for example TPU) and by the additive manufacturing process.

The central portion 221 comprises one or more compartments of the same size, of the same shape, or conversely of different sizes and/or shapes. According to the particular example of FIG. 2, the central portion 221 comprises multiple compartments arranged like steps, the different compartments having different depths.

According to the example of FIG. 2, the central portion has a rectangular, for example square, cross section. According to another example, the central portion 221 has a circular cross section of smaller diameter than the diameter of the cup holder 100, for example to receive cups, cans or bottles whose diameters are smaller than the diameter of the cup holder support 100.

The shape and geometry of the upper portion 220 advantageously vary according to the one or more objects that are intended to be received by this upper portion. A variety of shapes and geometries are advantageously obtained by virtue of the method for manufacturing the device 2, i.e. powder bed fusion additive manufacturing.

According to the example of FIG. 2, the central portion 221 comprises a solid bottom which separates this central portion 221 from the lower portion 21, thereby preventing objects received by the central portion 221 from falling to the bottom of the lower portion 21.

According to one alternative embodiment, the device 2 is configured to occupy only a portion of the volume afforded by the cup holder support 100. According to this alternative, the device corresponds, for example, to half of the device 2, for example along the length or width of the device 2.

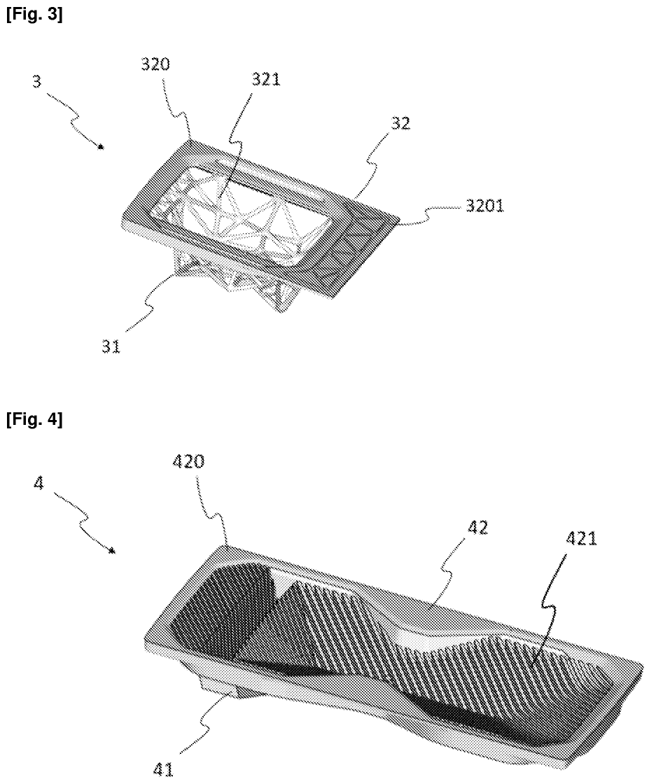

FIG. 3 schematically illustrates a device 3 for receiving items according to a second particular and non-limiting embodiment.

Like the device 2, the device 3 of FIG. 3 is formed of a lower portion 31 configured to slot into the cup holder support 100 and an upper portion 32 formed on the lower portion. The lower portion 31 and the upper portion 32 are produced or manufactured by powder bed fusion additive manufacturing, as one piece.

The device 3 advantageously at least partially has a lattice structure. The lower portion 31 is, for example, formed of a lattice comprising a plurality of cells, each cell being formed from strands of the material used to manufacture device 3.

For example, the upper portion 32 comprises a frame 320 formed of a shell of solid material, the frame 320 surrounding a central portion 321 formed of a lattice structure. The rigidity of the frame is advantageously greater than that of the central portion 321, this being obtained by virtue of the frame 320 being formed of a solid portion while the central portion is apertured as a result of the cells of which it is composed.

Such a device 3 affords the advantage of requiring less material for its manufacture than the device 2, resulting in the cost of manufacturing device 3 being lower than the cost of manufacturing the device 2.

However, the device 3 is not suitable for receiving small objects such as coins which would pass through the latticework and fall to the bottom of the cup holder 100. Such a device 3 is, however, suitable for receiving larger objects such as cell phones, a pair of spectacles, etc.

FIG. 4 schematically illustrates a device 4 for receiving items according to a third particular and non-limiting embodiment.

Like the devices 2 and 3, the device 4 of FIG. 4 is formed of a lower portion 41 configured to slot into one or two cup holder supports 100 and an upper portion 42 formed on the lower portion. The lower portion 41 and the upper portion 42 are produced or manufactured by powder bed fusion additive manufacturing, as one piece.

The example of FIG. 4 corresponds to a device 4 for receiving items that is configured to cover two cup holder supports formed side by side. To that end, the lower portion 41 is configured to fit into one of the two cup holder supports or, according to another embodiment, the lower portion 41 comprises two distinct sections which are each intended to be inserted by slotting into a cup holder support.

The device 4 is also suitable for covering a single cup holder support, with the dimensions of the device 4 being greater than those of devices 2 and 3, in particular the dimension along the longitudinal axis of the device 4.

According to the example of FIG. 4, the upper portion 42 comprises a frame 420 surrounding a central portion 421 which comprises a solid bottom separating this central portion from the lower portion 41, the surface forming the bottom being provided with striations or slats.

Of course, the configuration of the device 4 is not limited to the example illustrated but extends to any configuration, for example a lattice structure as for the device 3, or with one or more compartments as for the device 2.

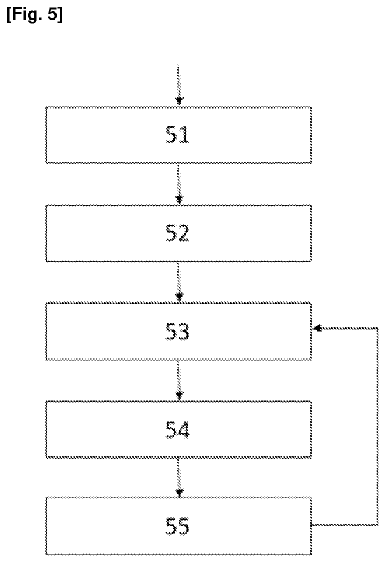

FIG. 5 illustrates a flowchart of the various steps of a method for manufacturing an object receiving device such as the device 2, 3 or 4 described with reference to FIGS. 2 to 4, according to one particular and non-limiting exemplary embodiment.

The method is, for example, implemented by a 3D printer. The method advantageously implements a powder bed fusion additive manufacturing method, for example SLS, MJF or HP MJF method.

In a first step 51, data representative of a three-dimensional (3D) model of the object receiving device are received. These data are, for example, received from a computer connected to the 3D printer via a wired link (for example Ethernet or USB) or via a wireless link (for example of Wi-Fi®). According to another example, these data are received from a data storage device, such as a USB key, inserted into an interface of the 3D printer provided for this purpose.

In a second step 52, a powder bed is deposited on a build platform by an element of the 3D printer provided for this purpose. The powder corresponds to TPU for example.

In a third step 53, the powder bed deposited in the second step is scanned by a laser, the scanning being controlled by a control unit of the 3D printer according to instructions obtained from the received data. According to one alternative embodiment, when the printing method implemented corresponds to an MJF or HP MJF method, a liquid binder is deposited on the powder bed by one or more nozzles of a printing head of the 3D printer before scanning or as scanning progresses.

In a fourth step 54, the build platform is lowered by a determined height, for example a height of between 20 and 80 μm. Such a height corresponds to the height of each layer or stratum for obtaining the object receiving device.

In a fifth step 55, a new powder bed (i.e. a new layer of powder) is deposited on the layer previously obtained in step 53.

The method continues by repeating steps 53, 54 and 55 and finishes with a scanning step 53 when the last layer for obtaining the item receiving device by 3D printing has been deposited.

According to one optional alternative, the method further comprises one or more steps of finishing by processing the external surfaces of the object receiving device.

According to another optional alternative, the method further comprises a step of painting the external surfaces of the object receiving device by applying one or more layers of paint.

Of course, the described devices and methods are not limited to the embodiments described hereinbefore but extends to a vehicle, for example a car or more generally an autonomous land motor vehicle, comprising one or more object receiving devices such as the device 2, 3 or 4.

1. An object receiving device for a vehicle, said device being obtained by powder bed fusion additive manufacturing and being formed of a flexible material, said device comprising:
a lower portion shaped to fit securely at least partially into a cup holder support of said vehicle;
an upper portion formed on said lower portion, said upper portion being configured to receive and hold at least one object.

2. The device as claimed in claim 1, wherein said flexible material corresponds to a thermoplastic polyurethane.

3. The device as claimed in claim 1, wherein said upper portion comprises a frame surrounding a central portion, said frame having a rigidity that is greater than the rigidity of said central portion, said central portion being configured to receive and hold said at least one object.

4. The device as claimed in claim 3, wherein said central portion comprises a set of striations formed parallel to one another.

5. The device as claimed in claim 3, wherein said central portion comprises a plurality of compartments of different sizes and/or shapes.

6. The device as claimed in claim 3, wherein said central portion has a cylindrical shape with a diameter smaller than the diameter of said cup holder support.

7. The device as claimed in claim 3, wherein said central portion has a lattice structure.

8. The device as claimed in claim 1, wherein said upper portion comprises a solid bottom separating said upper portion from said lower portion.

9. A method for manufacturing the object receiving device for a vehicle as claimed in claim 1, said method comprising the following steps:
receiving data representative of a three-dimensional model of said device;
depositing a powder bed on a build platform to form a powder layer;
scanning said powder layer with a laser controlled according to said data;
lowering said build platform by a height corresponding to a layer height;
depositing a new powder bed on the scanned powder layer;
repeating the scanning, lowering and new deposition steps until the last powder layer is deposited and said last powder layer is scanned.

10. A vehicle comprising the object receiving device as claimed in claim 1.
